(19) United States
(12) Patent Application Publication
(10) Pub. No.: US 2022/0297667 A1
(43) Pub. Date: Sep. 22, 2022

(54) INFORMATION COLLECTING DEVICE, VEHICLE, AND INFORMATION COLLECTING METHOD

(71) Applicant: TOYOTA JIDOSHA KABUSHIKI KAISHA, Toyota-shi Aichi-ken (JP)

(72) Inventor: Yasuhide Kurimoto, Kasugai-shi Aichi-ken (JP)

(21) Appl. No.: 17/696,418

(22) Filed: Mar. 16, 2022

(30) Foreign Application Priority Data
Mar. 22, 2021 (JP) 2021-047170

(51) Int. Cl. B60W 20/13; G07C 5/00; B60W 20/20; G07C 5/08

(52) U.S. Cl. CPC B60W 20/13; G07C 5/008; B60W 20/20; G07C 5/0816; B60W 2510/08

(57) ABSTRACT

A processing device of a server provides a predetermined price, based on battery information received by a communication device, to a user of a vehicle that transmits the battery information. The processing device provides a user of a vehicle transmitting second information as the battery information with a price higher than that provided to a user of a vehicle transmitting first information as the information, it being determined that there is a larger need for collecting the second information than the first information.

### CROSS REFERENCE TO RELATED APPLICATIONS

This nonprovisional application claims priority to Japanese Patent Application No. 2021-047170 filed on Mar. 22, 2021 with the Japan Patent Office, the entire contents of which are hereby incorporated by reference.

### BACKGROUND

### Field

The present disclosure relates to an information collecting apparatus, a vehicle, and an information collecting method, and more particularly, to a technique for collecting information of a power storage device from a vehicle equipped with a power storage device for traveling.

### Description of the Background Art

Japanese Patent Laying-Open No. 2017-178077 discloses a hybrid vehicle capable of promoting the use of external charging in which a battery is charged using a power source outside the vehicle. In this hybrid vehicle, a usage index indicating the degree of usage of external charging in a predetermined period of time is transmitted to a system outside the vehicle. Thus, the system can provide various services to the vehicle and impose various penalty on the vehicle based on the received usage index.

Information on the power storage device can be collected from a vehicle on which the power storage device for driving (e.g., battery) is mounted, reflected in the development of the next vehicle, the quality of the power storage device can be monitored, and deterioration estimation of the power storage device can be performed. However, since the collected information may include information that can be referred to as personal information such as the position information and operation status of the vehicle in which the power storage device is mounted, the user may refuse to provide the information, or the collected area may be biased, and sufficient information may not be collected for the above purpose.

### SUMMARY

The present disclosure has been made to solve such a problem, and an object of the present disclosure is to provide an information collecting apparatus, a vehicle, and an information collecting method capable of sufficiently collecting information on a power storage device from a vehicle on which the power storage device for driving is mounted.

The presently disclosed information collecting apparatus collects information of a power storage device from a vehicle equipped with the power storage device for traveling, and comprises: a communication device that communicates with the vehicle; and a processing device. The processing device provides a predetermined price, based on the information of the power storage device received by the communication device, to a user of a vehicle transmitting the information. The information includes first information and second information. The second information is defined as information having a higher need for collection than the first information. And the processing device provides a user of a vehicle transmitting the second information as the information with a price higher than that provided to a user of a vehicle transmitting the first information as the information.

According to the above-described information collecting apparatus, the user of the vehicle that transmits the second information as the information of the power storage device is given a higher price than the user of the vehicle that transmits the first information, and information (in this case, the second information) for which there is a larger need for collection can be collected effectively. Therefore, according to the information collecting apparatus, it is possible to sufficiently collect the information of the power storage device from the vehicle on which the power storage device for traveling is mounted.

The processing device may provide the price to the user of the vehicle transmitting the information of the power storage device at a frequency of one or more times for a first predetermined period of time over a second predetermined period of time longer than the first predetermined period of time.

With this configuration, the information of the power storage device can be collected repeatedly and effectively over the second predetermined period of time.

The second predetermined period of time may be a period of time originating from a launch date of the vehicle.

In order to collect the information of the power storage device, reflect the information in the development of the next vehicle, monitor the quality of the power storage device, and estimate the degradation of the power storage device, information of an initial stage of several years (for example, three years) from the launch date of the vehicle is important. With the above configuration, information on the power storage device that can be used in the development of the next vehicle or the like can be collected effectively.

Of the information of the power storage device collected through the communication device, the second information may be information having a smaller collection record than the first information.

This makes it possible to effectively collect information of the power storage device having a small collection record.

Of the information of the power storage device collected through the communication device, the second information may be information collected in an area designated in advance as any one of an area of a severely high temperature, a cold area, an area at a high altitude, and an area having a large difference in level.

This makes it possible to effectively collect information useful for estimation of deterioration of the power storage device, such as an area of a severely high temperature, a cold area, an area with a high altitude, and an area having a large difference in level.

The processing device may signal via the communication device to the vehicle an area in which the second information is collected.

Alternatively, the processing device may notify a terminal of the user of the vehicle of an area in which the second information is collected.

This increases the likelihood that the user of the vehicle will travel in the area where the second information is collected for a high price. As a result, the second information for which there is a large need for collection can be collected effectively.

The processing device may provide the information received by the communication device with a rank depending on a predetermined level of need, and determine the price depending on the rank.

This increases the possibility that information for which there is a larger need can be collected.

The processing device may provide the information received by the communication device with a rank depending on an area in which the information is collected, and determine the price depending on the rank.

By setting a higher rank for information collected in an area where the information is only collected in a limited amount, it is possible to effectively collect rare information in that area.

The processing device may provide the information received by the communication device with a rank depending on how the power storage device is used, and determine the price depending on the rank.

By setting a higher rank for a vehicle having travelled a long distance, a frequently externally charged vehicle, and the like, information useful for estimation of deterioration of the power storage device or the like can be collected effectively.

Further, the presently disclosed vehicle comprises: a power storage device for traveling; a communication device that communicates with an information collecting apparatus external to the vehicle; and a control device that controls the communication device to transmit information of the power storage device to the information collecting apparatus. The information collecting apparatus provides a predetermined price, based on the information the power storage device collected, to a user of a vehicle transmitting that information. The information includes first information and second information. The second information is defined as information having a higher need for collection than the first information. And when the communication device transmits the second information as the information of the power storage device to the information collecting apparatus, the communication device receives a higher price from the information collecting apparatus than when the communication device transmits the first information as the information to the information collecting apparatus.

In the vehicle described above, when the second information is transmitted as the information of the power storage device to the information collecting apparatus, a higher price can be obtained than when the first information is transmitted to the information collecting apparatus. Therefore, the information collecting apparatus can effectively collect information (the second information) for which there is a large need for collection. Thus, according to the vehicle, the information collection apparatus can sufficiently collect the information of the power storage device from the vehicle on which the power storage device for traveling is mounted.

The presently disclosed information collecting method is a method for collecting information of a power storage device from a vehicle equipped with the power storage device for traveling and comprises: receiving the information of the power storage device from the vehicle; and providing a predetermined price, based on the information of the power storage device received, to a user of a vehicle transmitting the information. The information includes first information and second information. The second information is defined as information having a higher need for collection than the first information. The step of providing includes providing a user of a vehicle transmitting the second information as the information of the power storage device with a price higher than that provided to a user of a vehicle transmitting the first information as the information.

In the above-described information collecting method, the user of the vehicle that transmits the second information as the information of the power storage device is given a higher price than the user of the vehicle that transmits the first information, and information (the second information) for which there is a larger need for collection can be collected effectively. Therefore, according to this information collecting method, it is possible to sufficiently collect the information of the power storage device from the vehicle on which the power storage device for traveling is mounted.

These and other objects, features, aspects, and advantages of the present disclosure will become apparent from the following detailed description taken in conjunction with the accompanying drawings.

### BRIEF DESCRIPTION OF THE DRAWINGS

FIG. 1 is a diagram schematically showing an overall configuration of an information collection system according to an embodiment.

FIG. 2 is a diagram showing an example of a configuration of a vehicle.

FIG. 3 is a diagram showing a detailed configuration of a battery ECU of the vehicle and a server.

FIG. 4 is a diagram showing an example of battery information collected by a battery ECU.

FIG. 5 is a flowchart showing an example of a procedure of processing executed by a server.

FIG. 6 is a flowchart showing an example of a procedure of processing executed by a battery ECU of the vehicle.

FIG. 7 is a flowchart illustrating an example of a procedure of processing executed by a server according to the first modification.

FIG. 8 is a diagram showing a configuration of a server according to a second modified example.

FIG. 9 is a flowchart illustrating an example of a procedure of processing executed by a server according to a third modification.

FIG. 10 is a flowchart showing still another example of the procedure of processing executed by the server.

FIG. 11 is a flowchart showing still another example of the procedure of processing executed by the server.

### DETAILED DESCRIPTION

Hereinafter, embodiments of the present disclosure will be described in detail with reference to the drawings. In the drawings, the same or corresponding portions are denoted by the same reference numerals, and the description thereof will not be repeated.

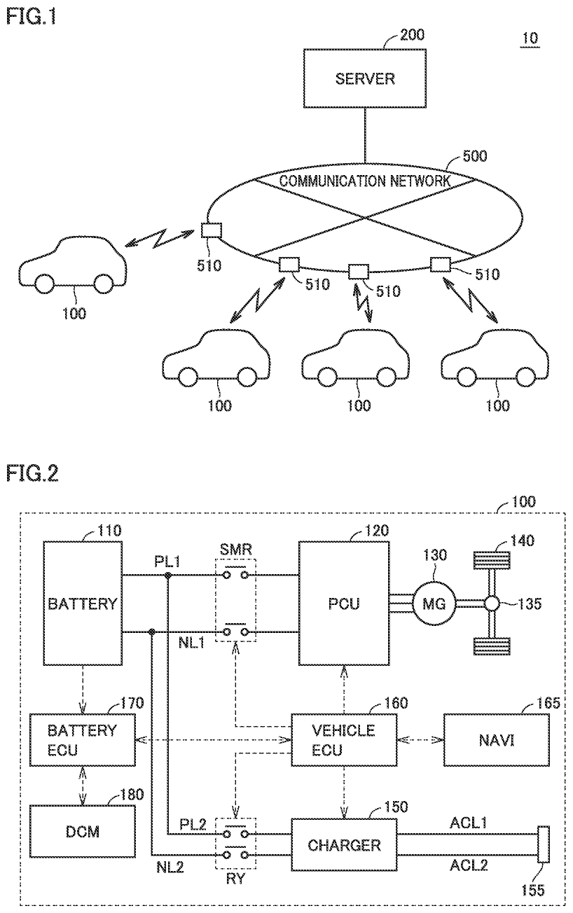

FIG. 1 schematically shows an overall configuration of an information collection system 10 according to an embodiment. Referring to FIG. 1, an information collection system 10 includes a plurality of electric powered vehicles (Hereinafter, the vehicle is also simply referred to as a “vehicle”) 100 and a server (information collecting apparatus) 200. The vehicle 100 and the server 200 are configured to communicate with each other via a communication network 500 such as the Internet or a telephone line. Each vehicle 100 is connected to the communication network 500 through the base station 510 of the communication network 500 and can communicate with the server 200.

As will be described later with reference to FIG. 2, each vehicle 100 is an electric powered vehicle (Hereinafter, it is also referred to as “BEV (Battery Electric Vehicle)”.) that generates driving force by using electric power from a mounted battery. Each vehicle 100 can charge a battery using electric power supplied from a power source outside the vehicle (external charging). In the present embodiment, each vehicle 100 is configured to be able to transmit various kinds of information of a mounted battery to the server 200 via the communication network 500.

The server 200 communicates with each vehicle 100 via the communication network 500, and exchanges various information with each vehicle 100. The configuration and operation of the server 200 will be described in detail later.

FIG. 2 is a diagram showing an example of the configuration of the vehicle 100. Referring to FIG. 2, vehicle 100 includes a battery (power storage device) 110, a system main relay SMR, a power control unit (PCU) 120, a motor generator 130, a power transmission gear 135, and a drive wheel 140. The vehicle 100 further includes a charger 150, an inlet 155, a charging relay RY, a vehicle ECU (Electronic Control Unit) 160, a navigation device 165, a battery ECU (control device) 170, and a communication module (communication device) 180.

The battery 110 is a secondary battery that can be charged and discharged, and is, for example, a lithium ion secondary battery, a nickel-hydrogen secondary battery, or the like. Instead of the battery 110, a power storage element such as an electric double layer capacitor may be used. The battery 110 outputs detected values of the voltage, current, and temperature of the battery 110 detected by a monitoring unit (not shown) to the battery ECU 170.

The PCU 120 is a driving device for driving the motor generator 130, and includes a power conversion device such as a converter or an inverter (none of which are shown). The PCU 120 is controlled by the vehicle ECU 160, and converts DC power received from the battery 110 into AC power for driving the motor generator 130.

The motor generator 130 is an AC rotating electrical machine, and is, for example, a permanent magnet type synchronous motor including a rotor in which permanent magnets are embedded. The output torque of the motor generator 130 is transmitted to the drive wheel 140 through the power transmission gear 135. Further, the motor generator 130 can generate power by the rotational force of the drive wheel 140 when braking the vehicle 100. The generated power is converted into the charging power of the battery 110 by the PCU 120.

Vehicle ECU 160 controls various vehicle devices such that vehicle 100 is in a desired state based on signals from various sensors (not shown), information of battery 110 from battery ECU 170, information from navigation device 165, and the like. For example, the vehicle ECU 160 controls the PCU 120 to execute various controls for realizing the travel of the vehicle 100. In addition, the vehicle ECU 160 executes charging (external charging) of the battery 110 by the charger 150 based on the information of the battery 110.

The navigation device 165 identifies the position of the vehicle 100 based on radio waves from an artificial satellite (not shown). The navigation device 165 executes various navigation processes of the vehicle 100 using the specified position information. The navigation device 165 displays the results of various navigation processes on a display.

The charger 150 is connected to the battery 110 via a charging relay RY. The charger 150 is connected to the inlet 155 by power lines ACL1 and ACL2. The charger 150 is controlled by the vehicle ECU 160, and converts the power input from the inlet 155 into the charging power of the battery 110 during external charging.

The battery ECU 170 receives detected values of the voltage, current, temperature, and the like of the battery 110 from a monitoring unit (not shown). The battery ECU 170 then calculates SOC (State Of Charge), full charge capacity, internal resistance value, and the like of the battery 110 based on the detected values. Various known methods can be used for these calculation methods. For example, regarding SOC, a method using an OCV-SOC curve (map or the like) indicating a relationship between an OCV (Open Circuit Voltage) and SOC, a method using an integrated value of charge/discharge currents, or the like can be used.

The communication module 180 is in-vehicle DCM (Data Communication Module), and is configured to be capable of two-way data communication with a communication apparatus of the server 200 through the communication network 500 (FIG. 1). The communication module 180 can transmit various information of the battery 110 collected or calculated by the battery ECU 170 to the server 200 through the communication network 500.

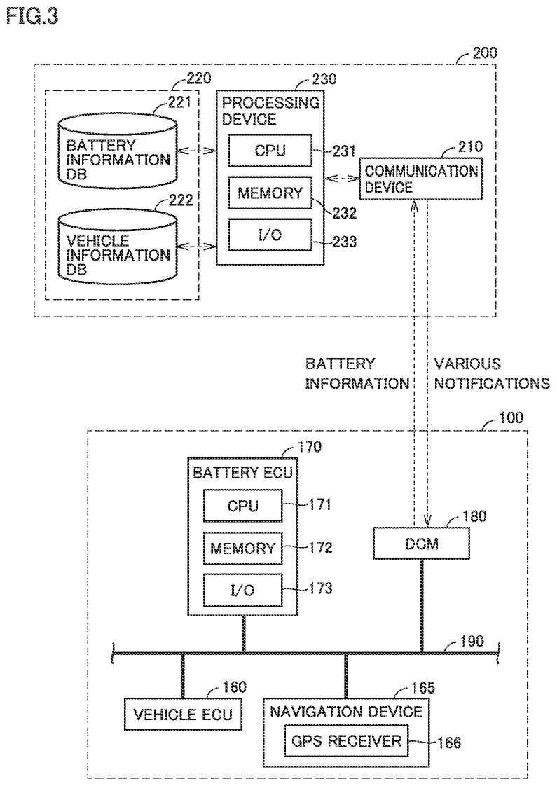

FIG. 3 is a diagram showing a detailed configuration of the battery ECU 170 of the vehicle 100 and the server 200. Referring to FIG. 3, battery ECU 170 is connected to in-vehicle network 190 such as CAN (Controller Area Network), and can communicate with communication module 180, vehicle ECU 160, navigation device 165, and the like, which are also connected to in-vehicle network 190, through in-vehicle network 190.

The battery ECU 170 includes CPU (Central Processing Unit) 171, a memory 172, and an input/output buffer 173. The memory 172 includes a ROM (Read Only Memory) and a RAM (Random Access Memory) (both not shown). The CPU 171 loads a program stored in the ROM into a RAM or the like and executes the program. Various processes executed by the battery ECU 170 are described in the programs stored in the ROM.

The battery ECU 170 collects various information (data) of the battery 110. Specifically, the battery ECU 170 receives detected values of the voltage, current, temperature, and the like of the battery 110 from the battery 110. Further, the battery ECU 170 calculates SOC, full charge capacity, internal resistance, and the like of the battery 110 based on these detected values. These pieces of information (each detected value and each calculated value) collected by the battery ECU 170 are accumulated in a storage device (An HDD (Hard Disk Drive), an SSD (Solid State Drive), or the like) (not shown).

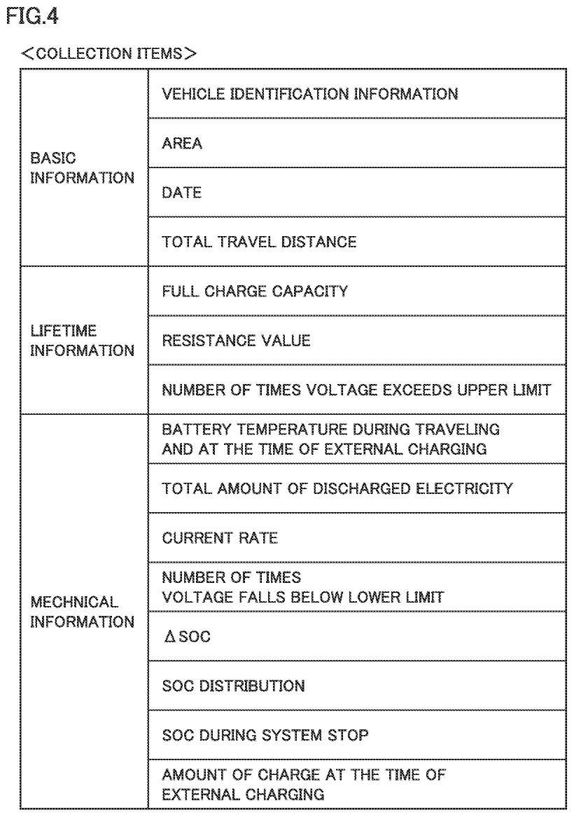

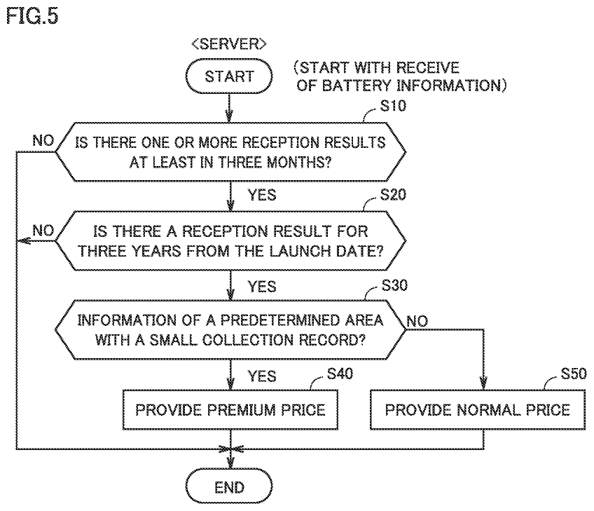

FIG. 4 is a diagram showing an example of information on the batteries 110 collected by the battery ECU 170. Referring to FIG. 4, the information (Hereinafter, this information may be simply referred to as “battery information”.) of battery 110 includes, for example, basic information, lifetime information, and technical information. The basic information includes, for example, vehicle identification information for identifying the vehicle 100, the area and date in which the information was collected, and data such as the total travel distance of the vehicle 100. The vehicle identification information includes an ID for identifying the vehicle, a launch date of the vehicle (year, month, day launched on the market), and the like. The area is identified from the location of the vehicle 100 when information is collected, and the location of the vehicle 100 is identified by the navigation device 165.

The lifetime information is information related to the life of the battery 110, and includes, for example, data such as the full charge capacity, the resistance value, and the number of times the voltage exceeds the upper limit value of the battery 110.

The technical information is information related to the state of the battery 110, and includes, for example, data such as the temperature of the battery 110 (the temperature at the time of traveling and the temperature at the time of external charging), the total amount of discharged electricity of the battery 110, the current rate, the number of times the voltage falls below the lower limit value, ASOC indicating the amount of change in SOC, the distribution of SOC, SOC at the time of system stoppage of the vehicle 100, and the amount of charge at the time of external charging.

Referring again to FIG. 3, battery ECU 170 periodically collects the battery information shown in FIG. 4 during system startup of vehicle 100 and at the time of external charging. Note that the state in which the system of the vehicle 100 is started includes, for example, a state in which the start switch for instructing the start of the vehicle system is in the Ready-ON state, and a state in which the vehicle 100 is traveling. The external charging is performed, for example, when the connection between the connector of the charging cable extending from the external power supply and the inlet 155 (FIG. 2) is detected, and includes the operation of the charger 150.

When the collected battery information is permitted to be transmitted to the server 200, the battery ECU 170 can transmit the collected battery information to the server 200 through the communication module 180. Whether or not to transmit the battery information to the server 200 is determined by the user of the vehicle 100. The collected information includes information that can be referred to as personal information such as positional information and how the battery 110 is used. Therefore, in this embodiment, the user can determine whether or not to provide the battery information to the server 200. For example, the navigation device 165 may be configured such that the user can set whether or not to transmit the collected battery information to the server 200.

When the collected battery information is permitted to be transmitted to the server 200, the battery ECU 170 transmits the collected battery information to the server 200 by the communication module 180, for example, when the system of the vehicle 100 is stopped or when the external charging is finished. When the system of the vehicle 100 is stopped, for example, the state of the start switch is switched from Ready-ON to Ready-OFF. The end of external charging is, for example, when the connector of the charging cable is removed from the inlet 155. Therefore, even if the collected battery information is permitted to be transmitted to the server 200, the battery information is not collected by the battery ECU 170 and is not transmitted to the server 200 unless the system start-up or external charging of the vehicle 100 is performed.

The navigation device 165 includes a GPS receiver 166 that determines the position of the vehicle 100 based on radio waves from an artificial satellite (not shown). The navigation device 165 performs various navigation processes of the vehicle 100 using the position information (GPS information) of the vehicle 100 specified by the GPS receiver 166. For example, based on the position information of the vehicle 100 and road map data stored in a memory (not shown), the navigation device 165 calculates a travel route (a scheduled travel route or a target route) from the current position of the vehicle 100 to a destination, and outputs information of the target route to the vehicle ECU 160 (not shown).

The navigation device 165 outputs the position information of the vehicle 100 to the battery ECU 170 via the in-vehicle network 190. The position information is data of the area where the battery information is collected.

The server 200 includes a communication device 210, a storage device 220, and a processing device 230. The communication device 210 is configured to be capable of two-way data communication with the communication module 180 of the vehicle 100 through the communication network 500 (FIG. 1).

The storage device 220 includes a battery information database (DB) 221 and a vehicle information database (DB) 222. The battery information DB 221 stores battery information (various data shown in FIG. 4) collected from each vehicle 100 shown in FIG. 1. The battery information of each vehicle 100 collected in the battery information DB 221 is useful to an information user such as a developer of the next vehicle.

For example, the developer of the vehicle can grasp how to use the vehicle 100 in the market from the battery information collected in the battery information DB 221 and reflect it in the planning of the next vehicle. For example, it is possible to evaluate the average travel distance per day, the frequency of external charging, the EV ratio (the ratio of EV travel when the vehicle 100 is a hybrid electric vehicle), and the like in accordance with a region (may be a country level) using the collected information, and reflect the evaluation in the development of the next vehicle.

It is also possible to monitor the quality of the battery 110 from the battery information collected in the battery information DB 221. For example, the developer of the vehicle can evaluate whether or not the degradation of the battery 110 depending on how the vehicle 100 is used deviates from the prediction, and can reflect it in the development of the next vehicle. Alternatively, the degradation estimation formula of the battery 110 based on actual data in the market may be derived from the battery information collected in the battery information DB 221. For example, the developer of the vehicle can derive the degradation estimation formula of the battery 110 by correlating the usage of the vehicle 100 with the degradation of the battery 110.

The vehicle information DB 222 stores information on each vehicle 100. The vehicle information DB 222 stores, for each vehicle 100, data such as information for identifying a vehicle, a frequency of reception of battery information, an area where battery information was acquired, and information relating to a price (described later) for providing battery information.

The processing device 230 includes a CPU 231, a memory 232, and an input/output buffer 233. The memory 232 includes a ROM and a RAM (both not shown). The CPU 231 loads a program stored in the ROM into a RAM or the like and executes the program. The programs stored in the ROM describe various processes (described later) executed by the processing device 230.

As described above, by collecting the battery information from each vehicle 100, it is possible to reflect the information in the development of the next vehicle, monitor the quality of the battery 110, and estimate the degradation of the battery 110. However, since the collected information includes information that can also be referred to as personal information such as position information and operation status of the vehicle 100 in which the battery 110 is mounted, the user may refuse to provide the information. Further, in order to use such battery information for analysis and evaluation, not monotonic data but data of a period effective for analysis and evaluation and a certain amount of data is required. Furthermore, even when there is a local deviation in the collected information, sufficient information may not be collected in the development of the next vehicle.

Thus, in the information collection system 10 according to the present embodiment, the processing device 230 of the server 200 gives a price to the user of the vehicle 100 that provided the battery information based on the battery information collected through the communication device 210. The price is given to the user of the vehicle 100 that periodically provided information for a fixed period of time. As the battery information, information from the launch date of the vehicle 100 to about three years is particularly useful, and the predetermined period is, for example, three years. The periodic condition is, for example, one or more times in at least three months, but may be one or more times in one month or two months. The processing device 230 monitors the reception result of the battery information for each vehicle 100, and stores the monitoring result in the vehicle information DB 222.

The price may be given to the user of the vehicle 100 in a cache or a point such as a credit card. Alternatively, the price may be a discount such as expense of various services of the vehicle or expense of periodic inspection, or an increase in an assessment trade-in price of the vehicle. In some embodiments, these are used because they increase the opportunity to enter the vehicle dealer.

Further, the processing device 230 assigns a premium price added to the price to the user of the vehicle 100 that has transmitted information having a high need for information collection. In the present embodiment, a price of a premium is given to a user of the vehicle 100 that has provided battery information in a predetermined area with less collection performance. Among the battery information collected from each vehicle 100, information (second information) having a high need to collect such information is determined in advance. For example, in a sparse area or the like, the absolute number of vehicles is small, and battery information about how the vehicle is used in the area is hard to collect. In the present embodiment, information in a region in which collection results are smaller than those in other regions is set as information having high information collection needs.

In this way, an increase in the information collection amount of the battery 110 can be expected by giving a price to the user of the vehicle 100 that periodically provided the battery information for a predetermined period of time. Furthermore, by giving a premium price to the user of the vehicle 100 who has provided information with high information collection needs, battery information with high information collection needs can be collected effectively.

FIG. 5 is a flowchart showing an example of the procedure of processing executed by the server 200. A series of processes shown in this flowchart is started when battery information is received from each vehicle 100.

Referring to FIG. 5, when receiving the battery information, processing device 230 of server 200 identifies vehicle 100 that transmitted the battery information from the vehicle identification information included in the received battery information. Further, the processing device 230 refers to the vehicle information DB 222 and confirms the reception result of the battery information from the specified vehicle 100. Then, the processing device 230 determines whether or not there is one or more reception results at least in three months from the vehicle (step S10).

If NO in step S10, the processing device 230 stores the collected battery information in the battery information DB 221, writes the received result from the vehicle in the vehicle information DB 222, and then shifts the process to the end.

If it is determined in step S10 that there is one or more reception results from the vehicle at least in three months (YES in step S10), the processing device 230 determines whether there is a reception result from the vehicle for three years from the launch date of the vehicle (step S20).

If NO in step S20, the processing device 230 stores the collected battery information in the battery information DB 221, writes the received result from the vehicle in the vehicle information DB 222, and then shifts the process to the end, as in the case of NO in step S10.

If it is determined in step S20 that there is a reception record from the vehicle for three years from the launch date (YES in step S20), the processing device 230 determines whether or not the information of the area included in the received battery information is information of a predetermined area having a small collection record (step S30). The information of a predetermined area having a small collection record is information having a high need for information collection, and such an area is set by a user (such as a vehicle developer) of the server 200.

When it is determined that the battery information received this time is not information of a predetermined area having a small collection record (NO in step S30), the processing device 230 provides a normal price to the user of the vehicle 100 that transmitted the battery information (step S50). Specifically, the processing device 230 transmits the information related to the normal price to the vehicle 100 that has transmitted the battery information.

On the other hand, when it is determined in step S30 that the battery information received this time is information of a predetermined area having a small collection record (YES in step S30), the processing device 230 provides a premium price obtained by adding the premium to the normal price to the user of the vehicle 100 that transmitted the battery information (step S40). Specifically, the processing device 230 transmits the information related to the premium price to the vehicle 100 that has transmitted the battery information.

When the price information is transmitted to the vehicle 100 in step S40 or step S50, the processing device 230 stores the collected battery information in the battery information DB 221, writes the received result from the vehicle in the vehicle information DB 222, and then shifts the process to the end.

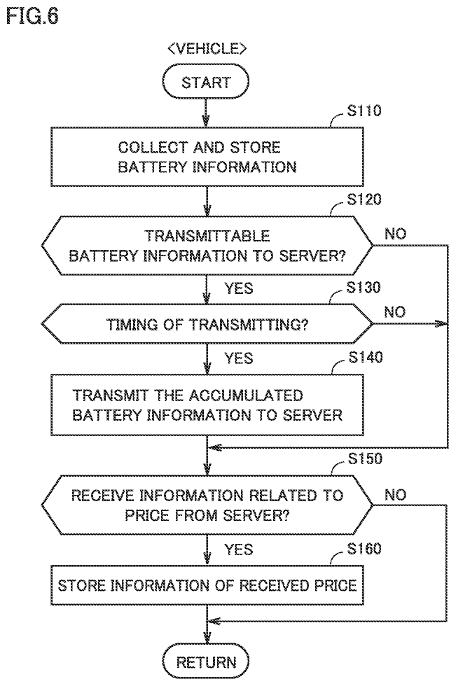

FIG. 6 is a flowchart showing an example of the procedure of processing executed by the battery ECU 170 of the vehicle 100. The series of processes shown in this flowchart is repeatedly executed at a predetermined cycle during system startup of the vehicle 100 and at the time of external charging.

Referring to FIG. 6, battery ECU 170 collects battery information (FIG. 4) and stores it in a storage unit (not shown) (step S110). Next, the battery ECU 170 determines whether or not the collected and accumulated battery information can be transmitted to the server 200 (step S120). Whether or not to transmit the battery information to the server 200 can be set by the user from the navigation device 165, for example. If NO in step S120, the process proceeds to step S150.

When the collected and accumulated battery information can be transmitted to the server 200 (YES in step S120), the battery ECU 170 determines whether or not the timing of transmitting the battery information to the server 200 has arrived (step S130). The timing at which the battery information is transmitted to the server 200 is when the system of the vehicle 100 is stopped or when the external charging is finished when the external charging is performed. If NO in step S130, the process proceeds to step S150.

When the battery information is transmitted to the server 200 (YES in step S130), the battery ECU 170 transmits the collected and accumulated battery information to the server 200 via the communication module 180 (step S140).

Next, the battery ECU 170 determines whether or not information relating to a price for transmitting the battery information to the server 200 is received from the server 200 (step S150). When the battery ECU 170 receives information relating to the price from the server 200 (YES in step S150), the battery ECU 170 stores the received information relating to the price in a storage unit (not shown) (step S160).

As described above, according to this embodiment, since a price is given to the user of the vehicle 100 that periodically provided the battery information for a fixed period of time, an increase in the information collection amount of the battery 110 can be expected. In addition, since the premium price is given to the user of the vehicle 100 who has provided the battery information in the area where the collection performance is low, the battery information with high information collection needs can be collected effectively.

In addition, in order to collect the information of the battery 110 and reflect the information to the development of the next vehicle, monitor the quality of the battery, or estimate the degradation of the battery, the information of the initial stage of about three years from the launch date of the vehicle 100 is important. According to the present embodiment, since the predetermined period is set to three years from the launch date of the vehicle 100, the information of the power storage device that can be used in the development of the next vehicle or the like can be effectively collected.

### Modified Example 1

In the above-described embodiment, the information having a high need for information collection is assumed to be information in an area where the collection record is small, but may be information in an area where the natural environment is severe, such as a severe heat area or a cold area. In a region in which the natural environment is severe, deterioration of the battery is likely to progress, and therefore, the battery information obtained from such a region is highly valuable and has high collection needs.

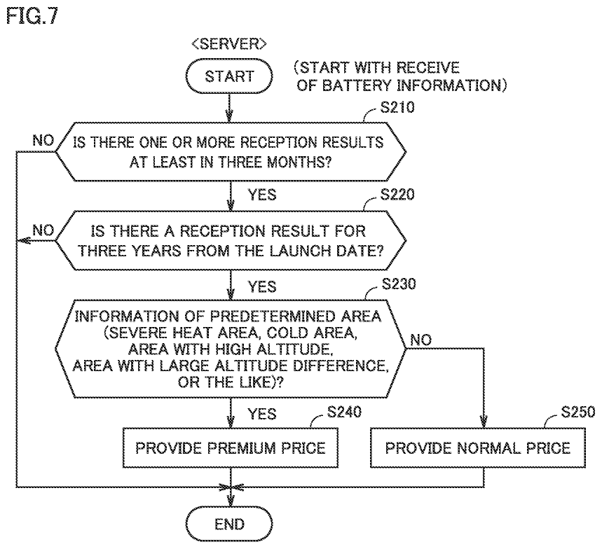

FIG. 7 is a flowchart showing an example of the procedure of processing executed by the server 200 in the first modified example. This flowchart corresponds to the flowchart shown in FIG. 5. A series of processes shown in this flowchart is also started when battery information is received from each vehicle 100.

Referring to FIG. 7, the processes of steps S210, S220, S240, and S250 are the same as the processes of steps S10, S20, S40, and S50 of the flowchart shown in FIG. 5, respectively.

In this flowchart, when it is determined in step S220 that there is a reception record from the vehicle over three years from the launch of the vehicle 100 (YES in step S220), the processing device 230 determines whether or not the information of the area included in the received battery information is information of a predetermined area in which the natural environment is severe (step S230). The predetermined area in which the natural environment is severe is, for example, a severe heat area, a cold area, an area with a high altitude, an area with a large altitude difference, or the like, and is set by a user (such as a vehicle developer) of the server 200 as information with high information collection needs.

When it is determined in step S230 that the currently received battery information is information of a predetermined region in which the natural environment is severe (YES in step S230), the processing device 230 proceeds to step S240, and assigns a premium price that is higher than usual to the user of the vehicle 100 that provided the battery information.

### Modified Example 2

In the embodiment described above, the information regarding the price (normal price/premium price) is transmitted to the vehicle 100 providing the battery information, but the information regarding the price may be notified to the terminal of the user of the vehicle 100 providing the battery information.

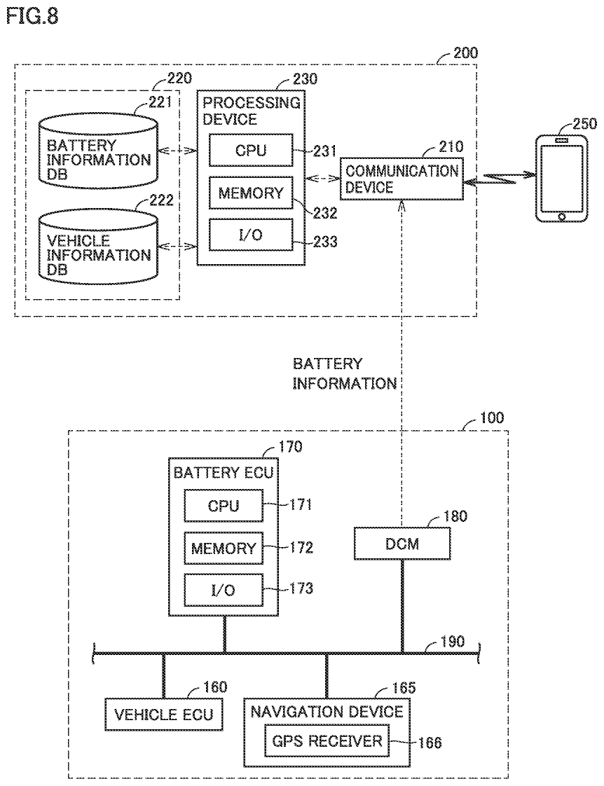

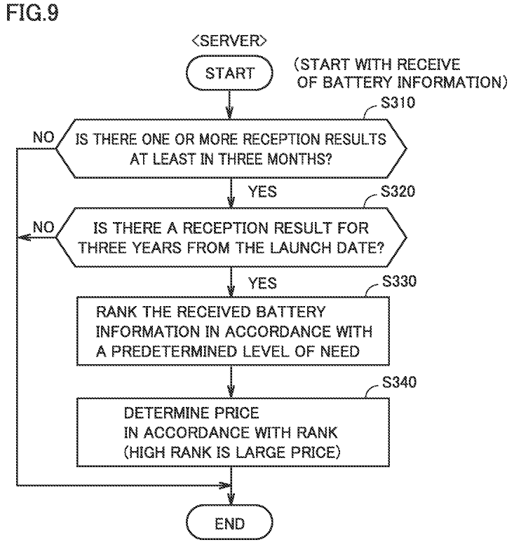

FIG. 8 is a diagram illustrating a configuration of a server 200 according to a second modification. This figure corresponds to the configuration diagram shown in FIG. 3. Referring to FIG. 8, in the second modified example, communication device 210 of server 200 is configured to be capable of wirelessly communicating with terminal device 250 of the user of vehicle 100. Then, the processing device 230 transmits the information related to the price given to the vehicle 100 that provided the battery information to the terminal device 250 of the user of the vehicle 100 through the communication device 210.

### Modified Example 3

In the above description, whether to give a normal price or a premium price is determined on the basis of whether or not the battery information received from the vehicle 100 is information of a region where the collection performance is low (the embodiment), or whether or not the battery information is information of a region where the natural environment is severe (modified example 1). In the third modified example, the battery information received from the vehicle 100 is ranked, and the price to be given is determined in accordance with the rank of the received battery information.

FIG. 9 is a flowchart showing an example of the procedure of processing executed by the server 200 in the third modified example. This flowchart corresponds to the flowchart shown in FIG. 5. A series of processes shown in this flowchart is also started when battery information is received from each vehicle 100.

Referring to FIG. 9, the processes of steps S310 and S320 are the same as the processes of steps S10 and S20 of the flowchart shown in FIG. 5, respectively.

In this flowchart, when it is determined in step S320 that there is a reception record from the vehicle over three years from the launch of the vehicle 100 (YES in step S320), the processing device 230 ranks the received battery information in accordance with a predetermined level of need (step S330). Specifically, the processing device 230 sets the rank of the battery information (e.g., battery information in the area where collection result is small) set as high needs to be higher than the rank of the normal battery information.

Then, the processing device 230 determines a price to be given to the user of the vehicle 100 that transmitted the battery information in accordance with the rank given in step S330 (step S340). Specifically, the processing device 230 determines the price according to the rank so that the price of the user of the vehicle 100 providing the battery information of the high rank becomes large.

Although ranking is performed in accordance with the height of the needs of the provided battery information in the above description, the provided battery information may be ranked in accordance with the area where the battery information is collected.

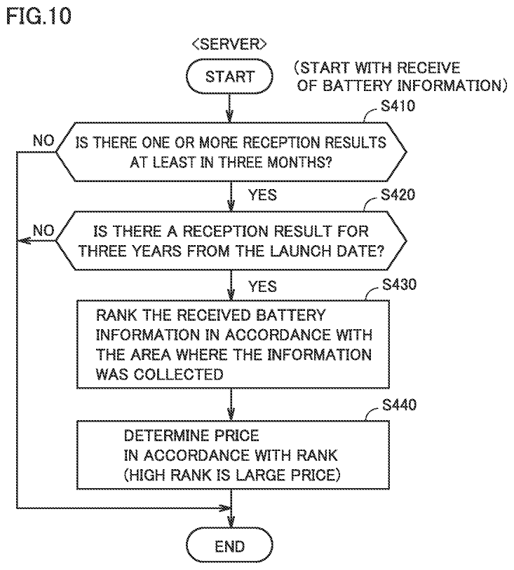

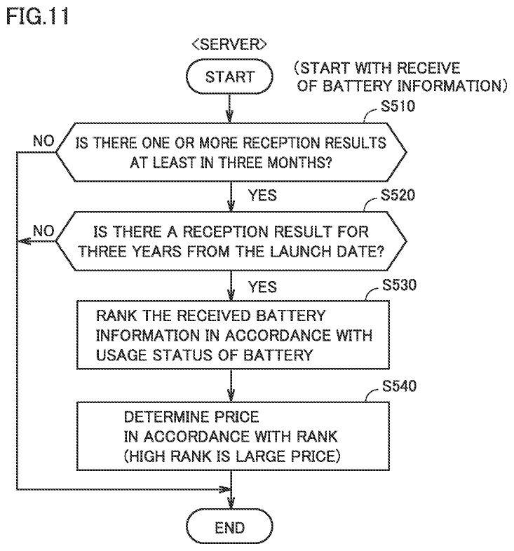

FIG. 10 is a flowchart showing still another example of the procedure of processing executed by the server 200. This flowchart corresponds to the flowchart shown in FIG. 9. A series of processes shown in this flowchart is also started when battery information is received from each vehicle 100.

Referring to FIG. 10, the processes of steps S410, S420, and S440 are the same as the processes of steps S310, S320, and S340 of the flowchart shown in FIG. 9, respectively.

In this flowchart, when it is determined in step S420 that there is a reception record from the vehicle over three years from the launch of the vehicle 100 (YES in step S420), the processing device 230 ranks the received battery information according to the area where the battery information is collected (step S430). For example, the processing device 230 may set the battery information collected in an area where the battery information is less likely to be collected (such as a sparse area where the absolute number of vehicles is small) to a higher rank than the battery information collected in an area where the battery information is more likely to be collected (such as an opportunity where the absolute number of vehicles is large). Alternatively, the battery information collected in a region where the temperature difference of the climate is large may be ranked higher than the battery information collected in a region where the temperature difference of the climate is small.

Thereafter, the process proceeds to step S440, and the price given to the user of the vehicle 100 that transmitted the battery information is determined in accordance with the rank given in step S430.

Alternatively, the provided battery information may be ranked according to the state of use of the battery. For example, the battery information may be ranked according to the travel distance of the vehicle 100, the frequency of external charging, or the like.

FIG. 11 is a flowchart showing still another example of the procedure of processing executed by the server 200. This flowchart also corresponds to the flowchart shown in FIG. 9. The series of processes shown in the flowchart is also started when the battery information is received from each vehicle 100.

Referring to FIG. 11, the processes of steps S510, S520, and S540 are the same as the processes of steps S310, S320, and S340 of the flowchart shown in FIG. 9, respectively.

In this flowchart, if it is determined in step S520 that there is a reception record from the vehicle over three years from the launch of the vehicle 100 (YES in step S520), the processing device 230 ranks the received battery information in accordance with the usage status of the battery 110 (step S530). For example, the processing device 230 may make the battery information received from the vehicle 100 having a long travel distance for one day higher in rank than the battery information received from the vehicle 100 having a short travel distance. Alternatively, the battery information received from the vehicle 100 with a high frequency of external charging during an appropriate period of time may be ranked higher than the battery information received from the vehicle 100 with a low frequency of external charging.

Thereafter, the process proceeds to step S540, and the price given to the user of the vehicle 100 that transmitted the battery information is determined in accordance with the rank given in step S530.

Although not particularly shown, the server 200 may transmit information on the area where the premium price is given to the provided battery information to each vehicle 100, or may notify the terminal device 250 of the user of each vehicle 100. The information of the area may be displayed on the map of the navigation device 165 in each vehicle 100, or the information of the area may be displayed on the map application or the like in each terminal device 250. This increases the possibility that the user of the vehicle 100 travels in an area to which the premium price is assigned, for a high price. As a result, battery information having a high need for information collection can be collected effectively.

It should be noted that, in the above-described embodiment and each modified example, the condition for providing a price is that there is one or more reception results in at least three months, but the frequency of reception is not limited to this, and may be one or more times in one month or one or more times in two months.

In addition, in the above description, the fact that the actual reception has been performed over three years from the launch date of the vehicle 100 is regarded as the condition for providing a price, but the period is not limited to this, and may be one year or two years from the launch date.

Although the present disclosure has been described and illustrated in detail, it is clearly understood that the same is by way of illustration and example only and is not to be taken by way of limitation, the scope of the present disclosure being interpreted by the terms of the appended claims.

What is claimed is:

1. An information collecting apparatus that collects information of a power storage device from a vehicle equipped with the power storage device for traveling, comprising:
a communication device that communicates with the vehicle; and
a processing device that provides a predetermined price, based on the information received by the communication device, to a user of a vehicle transmitting the information, wherein
the information includes first information and second information, the second information being defined as information having a higher need for collection than the first information,
the processing device provides a user of a vehicle transmitting the second information as the information with a price higher than that provided to a user of a vehicle transmitting the first information as the information.

2. The information collecting apparatus according to claim 1, wherein the processing device provides the price to the user of the vehicle transmitting the information at a frequency of one or more times for a first predetermined period of time over a second predetermined period of time longer than the first predetermined period of time.

3. The information collecting apparatus according to claim 2, wherein the second predetermined period of time is a period of time originating from a launch date of the vehicle.

4. The information collecting apparatus according to claim 1, wherein, of the information collected through the communication device, the second information is information having a smaller collection record than the first information.

5. The information collecting apparatus according to claim 1, wherein, of the information collected through the communication device, the second information is information collected in an area designated in advance as any one of an area of a severely high temperature, a cold area, an area at a high altitude, and an area having a large difference in level.

6. The information collecting apparatus according to claim 1, wherein the processing device signals via the communication device to the vehicle an area in which the second information is collected.

7. The information collecting apparatus according to claim 1, wherein the processing device notifies a terminal of the user of the vehicle of an area in which the second information is collected.

8. The information collecting apparatus according to claim 1, wherein the processing device provides the information received by the communication device with a rank depending on a predetermined level of need, and determines the price depending on the rank.

9. The information collecting apparatus according to claim 1, wherein the processing device provides the information received by the communication device with a rank depending on an area in which the information is collected, and the processing device determines the price depending on the rank.

10. The information collecting apparatus according to claim 1, wherein the processing device provides the information received by the communication device with a rank depending on how the power storage device is used, and the processing device determines the price depending on the rank.

11. A vehicle comprising:
a power storage device for traveling;
a communication device that communicates with an information collecting apparatus external to the vehicle; and
a control device that controls the communication device to transmit information of the power storage device to the information collecting apparatus, wherein
the information collecting apparatus provides a predetermined price, based on the information collected, to a user of a vehicle transmitting the information,
the information includes first information and second information, the second information being defined as information having a higher need for collection than the first information, and
when the communication device transmits the second information as the information to the information collecting apparatus, the communication device receives a higher price from the information collecting apparatus than when the communication device transmits the first information as the information to the information collecting apparatus.

12. An information collecting method for collecting information of a power storage device from a vehicle equipped with the power storage device for traveling, comprising:
receiving the information from the vehicle; and
providing a predetermined price, based on the information received, to a user of a vehicle transmitting the information, wherein
the information includes first information and second information, the second information being defined as information having a higher need for collection than the first information,
the providing includes providing a user of a vehicle transmitting the second information as the information with a price higher than that provided to a user of a vehicle transmitting the first information as the information.
